(19) United States
(12) Patent Application Publication
(10) Pub. No.: US 2023/0215885 A1
(43) Pub. Date: Jul. 6, 2023

(54) ADJUSTABLE WELL CAPACITY PIXEL FOR SEMICONDUCTOR IMAGING SENSORS

(71) Applicant: Shenzhen Goodix Technology Co., Ltd., Shenzhen (CN)

(72) Inventors: Yunfei GAO, San Diego, CA (US); Tae Seok OH, San Diego, CA (US)

(21) Appl. No.: 17/566,603

(22) Filed: Dec. 30, 2021

(51) Int. Cl. H01L 27/146

(52) U.S. Cl. CPC H01L 27/14614; H01L 27/14643

(57) ABSTRACT

An imaging pixel design is provide with a photo-sensor block structure that facilitates dynamic control of well capacity in the photodiode region (i.e., a “well capacity adjustment (WCA) gate photo-sensor block”). The photodiode region includes a doped well in which photocharge is accumulated responsive to exposure to incident illumination. The capacity of the well corresponds to a well potential. WCA structures (e.g., deep trench regions) form walls at least partially surrounding and capacitively coupling with the doped well, such that biasing of the WCA structures changes the well potential and the corresponding well capacity. As such, the WCA structures can be biased during integration to increase the well potential to a high level for large well capacity, and the WCA structures can be differently biased during photocharge transfer to decrease the well potential to a sufficiently low level that avoids lag and/or other conventional concerns.

### TECHNICAL FIELD

The present document relates to complementary metal-oxide semiconductor (CMOS) image sensors. More particularly, embodiments relate to adjustable well capacity pixel designs for use with CMOS image sensor (CIS) pixels.

### BACKGROUND

Many modern electronics applications include integrated digital cameras and/or other imaging systems, which are based on complementary metal-oxide semiconductor (CMOS) image sensor (CIS) technologies. A CIS can typically include an array of pixels, each including a single photo-sensor (e.g., photodiode), or a grouping of multiple photo-sensors. Each imaging pixel can include a photosensing element that responds to light to generate photocharge, and in-pixel circuitry for processing the generated photocharge to produce an electrical pixel output signal and for controlling operations of each imaging pixel. The in-pixel circuitry includes transistors for performing sensing and control functions.

Performance of an imaging sensor pixel relates to how well the pixel can convert photons into electrical charges. Such performance can depend on a number of physical and electrical characteristics of the pixel, such as well capacity, dynamic range, and conversion gain. Well capacity relates to the amount of charge that can be held by the imaging pixel during integration (i.e., during exposure to light, prior to readout). It can be desirable to have a large dynamic range, which indicates that the pixel performs well over a large range of lighting conditions, such as from very low-light conditions up to high-light conditions (i.e., where full well capacity, or FWC, may be reached). It can also be desirable to have higher conversion gain, which indicates a larger increase in output signal voltage with any increase in accumulated charge. Typically, the output signal level corresponds to the ratio between the accumulated charge in the well and the well capacitance. For example, a smaller well can tend to have less capacity to accumulate charge and correspondingly smaller well capacitance, which can tend to result in a larger change in output signal level for any change in charge accumulation in the well.

Doping profiles and/or other parameters can be adjusted and controlled during manufacturing of pixels to form photodiodes with a desired well size (e.g., a particular pin voltage potential). A larger well size can theoretically support a higher FWC, but it can also lead to spill-back lag after charge transfer. For example, if the highest fully-depleted potential of the photodiode is too high, residual accumulated charge may remain in the well after transfer, thereby manifesting as a lag. As such, conventional photodiodes tend to be designed with a lower fully-depleted potential and a smaller corresponding FWC to avoid spill-back lag and/or other concerns.

### BRIEF SUMMARY

Embodiments disclosed herein include, among others, an imaging pixel design with a unique photo-sensor block structure that provides for dynamic control of well capacity in the photodiode region, referred to herein as a well capacity adjustment (WCA) gate photo-sensor block. The photodiode region includes a doped well in which photocharge is accumulated responsive to exposure to incident illumination. The capacity of the well corresponds to a well potential. WCA structures (e.g., deep trench regions) form walls at least partially surrounding and capacitively coupling with the doped well, such that biasing of the WCA structures changes the well potential and the corresponding well capacity. As such, the WCA structures can be biased during integration to increase the well potential to a high level for large well capacity, and the WCA structures can be differently biased during photocharge transfer to decrease the well potential to a sufficiently low level that avoids lag and/or other conventional concerns.

According to a first set of embodiments, a method is provided for selective photodiode well capacity adjustment in an imaging sensor pixel. The method includes first configuring the WCA gate photo-sensor block to operate in an integration mode for an integration time window by: setting a transfer gate of a well-capacity-adjustment (WCA) gate photo-sensor block to form a potential barrier between a photodiode region of the WCA gate photo-sensor block and a floating diffusion (FD) region of the WCA gate photo-sensor block, the photodiode region having a doped well implanted in a semiconductor substrate to have a well capacity defined at least by a well potential; setting a WCA gate of the WCA gate photo-sensor block to a first biasing, the WCA gate integrated in the semiconductor substrate to form walls that at least partially surround and capacitively couple with the doped well, such that the first biasing pushes the well potential to a first well potential that corresponds to a full well capacity; and directing exposing the photodiode region to incident illumination to cause accumulation of photocharge in the doped well during the integration time widow. The method further includes second configuring the WCA gate photo-sensor block to operate in a transfer mode for a transfer time window subsequent to the integration time window by: setting the transfer gate to form a current channel between the doped well and the FD region; and setting the WCA gate to a second biasing to pull the well potential to a second well potential that corresponds to a reduced well capacity, the second well potential being less than a channel potential of the current channel, the channel potential being less than a FD potential of the FD region. In some such embodiments, the second configuring causes the photocharge accumulated in the doped well during the integration time window to transfer to the FD region via the current channel as transferred photocharge, and the method further includes third configuring the WCA gate photo-sensor block to operate in a spill-back suppression mode for a spill-back suppression time window subsequent to the transfer time window by re-setting the transfer gate to form the potential barrier between the doped well and the FD region while continuing the setting of the WCA gate to the second biasing. In some such methods, the method further includes fourth configuring the WCA gate photo-sensor block to operate in a readout mode for a readout time window subsequent to the spill-back suppression time window by directing readout of the transferred photocharge from the FD region by readout circuitry coupled with the FD region with the transfer gate set to form the potential barrier.

According to another set of embodiments, an imaging sensor pixel is provided. The pixel includes: a well-capacity-adjustment (WCA) gate photo-sensor block configured selectively to operate in at least an integration mode and a transfer mode, the WCA gate photo-sensor block comprising: a photodiode region having a doped well implanted into a semiconductor substrate to accumulate photocharge responsive to exposure of the WCA gate photo-sensor block to incident illumination, the doped well having a well capacity defined at least by a well potential; a WCA gate integrated in the semiconductor substrate to form walls that at least partially surround and capacitively couple with the doped well, such that the well potential is based at least on biasing of the WCA gate; a floating diffusion (FD) region implanted into the semiconductor substrate to have a FD potential; and a transfer gate to selectively form a current channel between the doped well and the floating diffusion region, the current channel having a channel potential less than the FD potential, wherein, in the integration mode, the WCA gate is first-biased to set the well potential to a first well potential corresponding to a full well capacity, and wherein, in the transfer mode, the WCA gate is second-biased to set the well potential to a second well potential that is less than the first well potential, is less than the channel potential, and corresponds to a reduced well capacity.

In another set of embodiments, a complementary metal-oxide semiconductor (CMOS) imaging sensor (CIS) is provided. The CIS includes: an array of imaging pixels, each imaging pixel comprising a well-capacity-adjustment (WCA) gate photo-sensor block, each WCA gate photo-sensor block including: a photodiode region having a doped well implanted into a semiconductor substrate to accumulate photocharge responsive to exposure of the WCA gate photo-sensor block to incident illumination, the doped well having a well capacity defined at least by a well potential; a WCA gate integrated in the semiconductor substrate to form walls that at least partially surround and capacitively couple with the doped well, such that the well potential is based at least on biasing of the WCA gate; a floating diffusion (FD) region implanted into the semiconductor substrate to have a FD potential; and a transfer gate to selectively form a current channel between the doped well and the floating diffusion region, the current channel having a channel potential less than the FD potential. The CIS also includes a controller coupled with the array of imaging pixels to selectively configure each imaging pixel to operate in at least an integration mode and a transfer mode, such that: the controller is to configure each imaging pixel to operate in the integration mode by setting the transfer gate of the imaging pixel to form a potential barrier between the doped well of the imaging pixel and the FD region of the imaging pixel, setting the WCA gate of the imaging pixel to a first biasing to push the well potential of the imaging pixel to a first well potential that corresponds to a full well capacity, and directing exposing the imaging pixel to incident illumination to cause accumulation of photocharge in the doped well of the imaging pixel during an integration time widow; and the controller is to configure each imaging pixel to operate in the transfer mode by setting the transfer gate of the imaging pixel to form a current channel between the doped well of the imaging pixel and the FD region of the imaging pixel, and setting the WCA gate of the imaging pixel to a second biasing to pull the well potential of the imaging pixel to a second well potential that corresponds to a reduced well capacity, the second well potential being less than a channel potential of the current channel, the channel potential being less than a FD potential of the FD region.

The drawings, the description and the claims below provide a more detailed description of the above and other aspects of transistors with a hybrid structure, their implementations and features of the disclosed technology.

### BRIEF DESCRIPTION OF THE DRAWINGS

The accompanying drawings, referred to herein and constituting a part hereof, illustrate embodiments of the disclosure. The drawings together with the description serve to explain the principles of the invention.

FIG. 1 shows a simplified block diagram of a portion of an illustrative digital imaging system, as context for various embodiments described herein.

FIG. 2 shows an example of a conventional CIS imaging pixel with conventional in-pixel circuitry.

FIGS. 3A-3C show a sequence of simplified energy band diagrams to illustrate conventional transfer of photocharges in a photodiode.

FIGS. 4A-4C show a sequence of simplified energy band diagrams to illustrate transfer of photocharges in a photodiode with an increased pinning voltage.

FIGS. 5A-5C show another sequence of simplified energy band diagrams to illustrate spill back during transfer of photocharges in a photodiode with an increased pinning voltage.

FIG. 6 shows an example of a novel well-capacity-adjustment-gate (WCAG) photo-sensor block, according to various embodiments described herein.

FIG. 7 shows a simplified timing diagram for controlling operation of a pixel that includes a WCAG photo-sensor block during an illustrative charge integration and transfer cycle, according to various embodiments.

FIGS. 8A-8D show a sequence of simplified energy band diagrams to illustrate transfer of photocharge in a WCAG photo-sensor block, according to various embodiments.

FIG. 9 shows a graph of an illustrative set of plots comparing operation of a conventional type of photo-sensor block with a WCAG photo-sensor block.

FIG. 10 shows a simplified planar layout view of a partial array of pixels having a contiguous implementation of the WCA structures, according to various embodiments described herein.

FIG. 11 shows a simplified planar layout view of a partial array of pixels having a non-contiguous implementation of the WCA structures, according to various embodiments described herein.

FIG. 12 shows a flow diagram of an illustrative method for selective photodiode well capacity adjustment in an imaging sensor pixel, according to embodiments described herein.

In the appended figures, similar components and/or features can have the same reference label. Further, various components of the same type can be distinguished by following the reference label by a second label that distinguishes among the similar components. If only the first reference label is used in the specification, the description is applicable to any one of the similar components having the same first reference label irrespective of the second reference label.

### DETAILED DESCRIPTION

In the following description, numerous specific details are provided for a thorough understanding of the present invention. However, it should be appreciated by those of skill in the art that the present invention may be realized without one or more of these details. In other examples, features and techniques known in the art will not be described for purposes of brevity.

Many modern electronics applications include integrated digital cameras and/or other imaging systems, which are based on complementary metal-oxide semiconductor (CMOS) image sensor (CIS) technologies. A CIS can typically include an array of pixels, each including a single photo-sensor (e.g., photodiode), or a grouping of multiple photo-sensors. Each imaging pixel can include a photosensing element that responds to light to generate photocharge, and in-pixel circuitry for processing the generated photocharge to produce an electrical pixel output signal and for controlling operations of each imaging pixel.

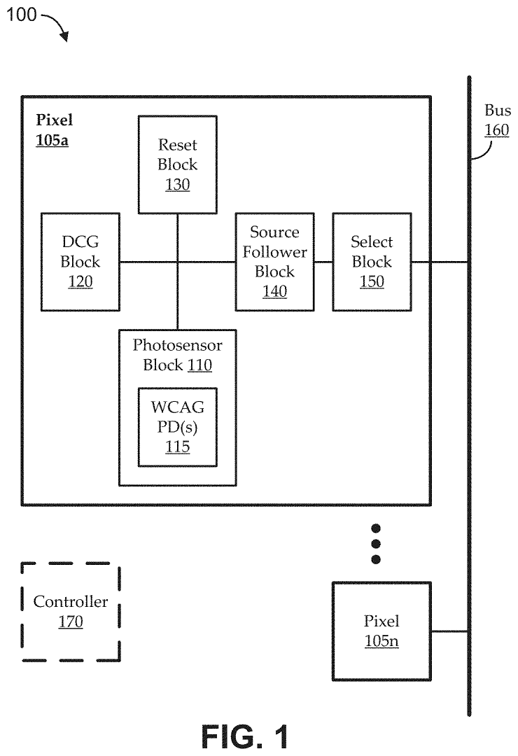

FIG. 1 shows a simplified block diagram of a portion of an illustrative digital imaging system 100, as context for various embodiments described herein. The digital imaging system 100 can be built around a complementary metal-oxide semiconductor (CMOS) image sensor (CIS) technology. Such a CIS system can typically include one or more arrays of pixels 105, such as a large number of pixels 105 arranged in rows and columns. Each pixel 105 can include a photo-sensor block 110, which can include a single photodiode 115, or a grouping of multiple photodiodes 115 (e.g., a set of four photodiodes). As described herein, the photo-sensor block 110 can be implemented with a novel type of photodiode(s) 115 referred to herein as well-capacity-adjustment-gate (WCAG) photodiodes.

The pixel 105 also includes additional components (in-pixel circuitry) to facilitate usage of the photo-sensor block 110 for optical sensing. As illustrated, embodiments can include a dual conversion gain (DCG) block 120, a reset block 130, a source-follower block 140, and a select block 150. Each can be implemented using at least one corresponding transistor. The reset block 130 can selectively reset the pixel 105 components. The source-follower block 140 can support conversion of outputs from the photo-sensor block 110 into an electrical signal indicative of optical information detected by the photo-sensor block 110. The select block 150 can support selection of the pixel 105 signals from among the array of pixels 105, for example responsive to a control signal received via a bus 160. For example, the bus 160 may be a column select bus, or the like.

Certain features described herein involve setting components of the pixel 105 array for multiple modes of operation, such as including some or all of an integration mode, a transfer mode, a spill-back suppression mode, and a readout mode. Further, certain features involve sequenced signaling (e.g., for biasing control) to support such modes. To direct such multi-mode operation, including controlling signaling to set components of the pixel 105 array, embodiments include control circuitry, illustrated as a controller 170. The controller can include a central processing unit CPU, an application-specific integrated circuit (ASIC), an application-specific instruction-set processor (ASIP), a digital signal processor (DSP), a field-programmable gate array (FPGA), a programmable logic device (PLD), a controller, a microcontroller unit, a reduced instruction set computer (RISC) processor, a complex instruction set computer (CISC) processor, a microprocessor, or the like, or any combination thereof. In some embodiments, the controller 170 is implemented on-chip with image sensor. For example, the array of pixels 105 and the controller 170 are implemented on a same integrated circuit.

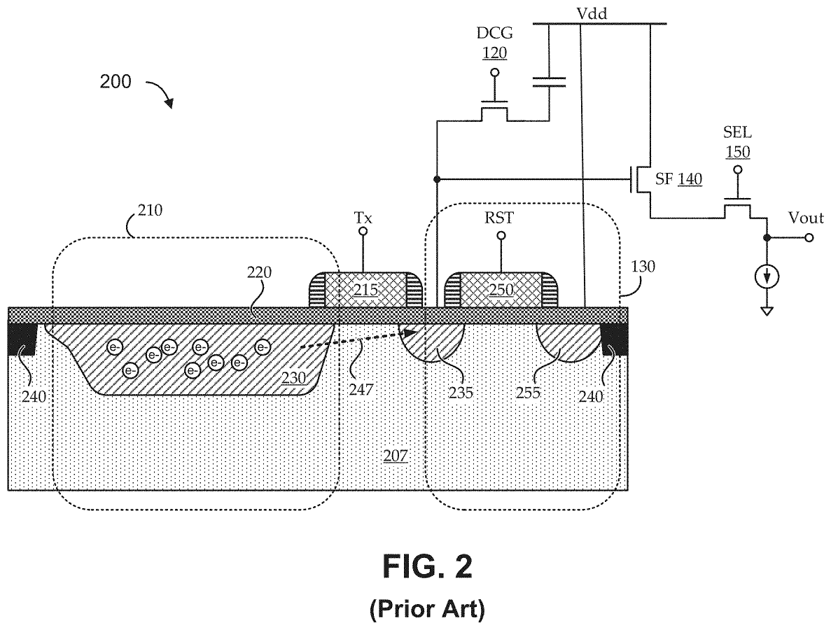

For added context, FIG. 2 shows an example of a conventional CIS imaging pixel 200 with conventional in-pixel circuitry. The pixel 200 can be an implementation of the conventional pixel 105 of FIG. 1, except with a conventional pinned photodiode (PPD) 210. For context, simplified representations are shown of the DCG block 120, the reset block 130, the source follower block 140, and the select block 150. The simplified PPD 210 and the reset block 130 (and other blocks of the pixel 200) can be implemented on a semiconductor substrate 207, such as a doped silicon wafer.

As illustrated, a transfer gate 215 can be activated by a Tx signal and can be isolated from the substrate 207 by an oxide layer 220. The substrate 207 can have a first doping type (e.g., P-type). The PPD 210 can be formed by implanting at least a collection region 230 of a second doping type (e.g., N-type) into the substrate 207 on one side of the transfer gate 215, and implanting a floating diffusion region 235 of the second doping type (e.g., N-type) into the substrate 207 on the other side of the transfer gate 215. The collection region 230 is generally referred to herein as the “well” of the PPD 210, and the maximum amount of photocharge that can be accumulated in the collection region 230 is the FWC of the PPD 210. Isolation regions 240 (e.g., shallow-trench isolation, STI) can be formed to electrically isolate structures of the pixel 200 from those of adjacent structures and/or pixels.

As photons reach the substrate 207, they can be converted into photocarriers (i.e., electrons and holes), one of which being attracted to and collected in the collection region 230. The accumulation of photocarriers in the collection region 230 can be considered generally as an accumulation of photocharge (also referred to herein generally as the accumulation of charge). For example, longer and/or brighter exposure can result in a greater accumulation of charge in the collection region 230. Activating the Tx signal can form a depletion region below the transfer gate 215, which effectively becomes a current channel between the two second-doping-type (e.g., N-type) regions: the collection region 230 and the floating diffusion region 235. As such, activation of the transfer gate 215 causes accumulated charge in the collection region 230 to transfer across the current channel to the floating diffusion region 235 (e.g., in the direction of arrow 247).

As illustrated, the in-pixel circuitry generally interfaces with the PPD 210 via the floating diffusion region 235. For example, components of the in-pixel circuitry are used to read out the accumulated charge after it is transferred to the floating diffusion region 235. Prior to transferring the accumulated charge from the collection region 230 to the floating diffusion region 235, the reset block 130 can be used to effectively flush accumulated charge from the floating diffusion region 235 to reset the pixel 200. Transferring the accumulated charge from the collection region 230 to the floating diffusion region 235 can effectively generate a gate voltage (corresponding to the amount of accumulated charge transferred to the floating diffusion region 235) at the gate of the source follower block 140. As illustrated, the select block 150 is coupled between a source terminal of the source follower block 140 and an output voltage terminal (Vout), and a constant current source is coupled between Vout and ground. As such, when the select block 150 is activated (e.g., as part of a row select operation), an output voltage is generated at Vout based on the gate voltage at the source follower block 140 (i.e., and thus based on the accumulated charge transferred to the floating diffusion region 235).

As illustrated, the reset block 130 can be implemented as a conventional MOSFET with an n-type source region (i.e., the floating diffusion region 235) and an n-type drain region 255 implanted in the semiconductor substrate 207 (e.g., p-doped silicon). Both the transfer gate 215 and the reset gate 250 can be implemented as polygate structures patterned on the substrate 207 on top of the gate oxide layer 220 (i.e., a metal-oxide layer). Conventionally, the gate oxide layer 220 is formed using a metal oxide, such as silicon dioxide. The gate oxide layer 220 forms a dielectric insulator layer between the polygate structures and formed current channels. As such, the gate oxide layer 220 electrically isolates both polygate structures from, and facilitates formations of respective channel regions below, the polygate structures. In particular, activating the transfer gate 215 forms a channel region between the collection region 230 and the floating diffusion region 235, and activating the reset gate 250 forms a channel region between the floating diffusion region 235 and the drain region 255. For example, applying a positive gate voltage to either polygate structure can attract negative charges to the channel region below the polygate structure in a p-doped substrate implementation, thereby forming an n-type current channel between adjacent n-type regions. Alternatively, applying a negative gate voltage to either polygate structure can attract positive charges to the channel region below the polygate structure in an n-doped substrate implementation, thereby forming a p-type current channel between adjacent p-type regions.

Performance of imaging pixels, such as pixel 200, can relate to how well the pixel can convert photons into electrical charges. Such performance can depend on a number of physical and electrical characteristics of the pixel, such as well capacity. As described above, the full well capacity (FWC) corresponds to the amount of photocharge that can be accumulated in the collection region 230 during integration (i.e., during exposure to light, prior to readout). It can be desirable in many applications to have a high FWC, such as to support higher dynamic range and improved signal-to-noise ratio. For example, higher dynamic range indicates that a pixel can perform well over a large range of lighting conditions, such as from very low-light conditions up to high-light conditions (i.e., where full well capacity, or FWC, may be reached).

However, achieving high FWC can be problematic. As a three-dimensional structure, the size of the well can be increased either by increasing its planar dimensions (i.e., its length and/or width with respect to layout view dimensions of the pixel), or by increasing its effective depth. The planar dimensions of the collection region 230 are typically limited by the overall pixel dimensions, which are shared by the photodiode(s) and any in-pixel circuitry. Such pixel layout dimensions have tended to decrease over time (e.g., with increasing demands for smaller image sensors and higher resolutions), which has tended to decrease the maximum layout area available for each photodiode collection region 230. The effective maximum depth of the collection region 230 can correspond to doping parameters and to a highest fully-depleted potential of the photodiode, sometimes referred to as the pinning voltage for a pinned photodiode, such as PPD 210. Doping profiles and/or other parameters can be adjusted and controlled during manufacturing of the photodiode to effectively set the pinning voltage potential to a desired level. A larger pinning voltage potential can theoretically support a deeper well in the same layout dimensions and a higher corresponding FWC. However, in conventional designs, increasing the maximum pinning voltage too much can lead to performance degradation, such as lag due to residual charge left in the collection region 230 after charge transfer.

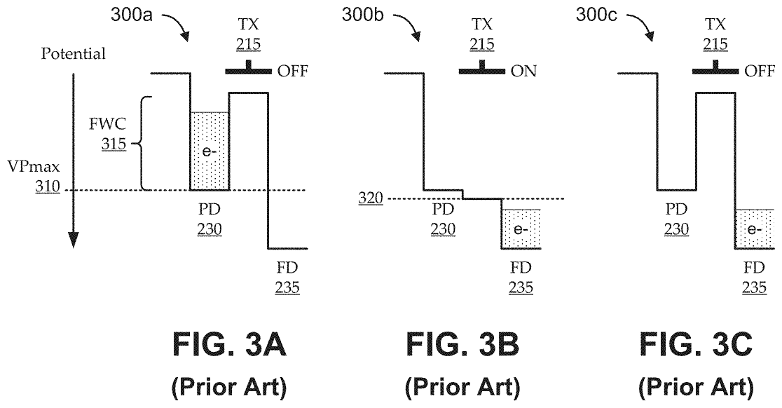

For example, FIGS. 3A-3C show a sequence of simplified energy band diagrams 300 to illustrate conventional transfer of photocharges in a photodiode, such as PPD 210 of FIG. 2. In each energy band diagram 300, the horizontal dimension represents a lateral dimension across structural regions, including the photodiode collection region (indicated as PD 230), the channel region below the transfer gate (indicated as TX 215), and the floating diffusion region (indicated as FD 235). In each energy band diagram 300, the vertical dimension represents a voltage potential (i.e., the arrow labeled “potential” indicates that lower on the page represents a higher voltage potential). The first energy band diagram 300a represents photocharge accumulation during integration, the second energy band diagram 300b represents movement of photocharges during transfer, and the third energy band diagram 300c represents locations of photocharges after transfer.

Turning first to FIG. 3A, the transfer gate 215 is turned OFF, providing a barrier to allow for accumulation of photocharge in the collection region 230. The maximum pinning voltage potential (indicated as VPmax 310) effectively sets the FWC 315 (assuming planar dimensions are constrained). During integration, photocharge accumulates and fills the well of the collection region 230. After some exposure time, the transfer gate 215 is turned ON, as illustrated in FIG. 3B. Now, the channel potential in the channel region below the transfer gate 215 is pushed down to a maximum channel potential 320, which allows the accumulated photocharge to flow out of the collection region 230 and into the even lower potential of the floating diffusion region 235. In FIG. 3C, after the transfer has occurred, the transfer gate 215 is turned OFF again, effectively trapping the transferred photocharge in the floating diffusion region 235 (e.g., for readout).

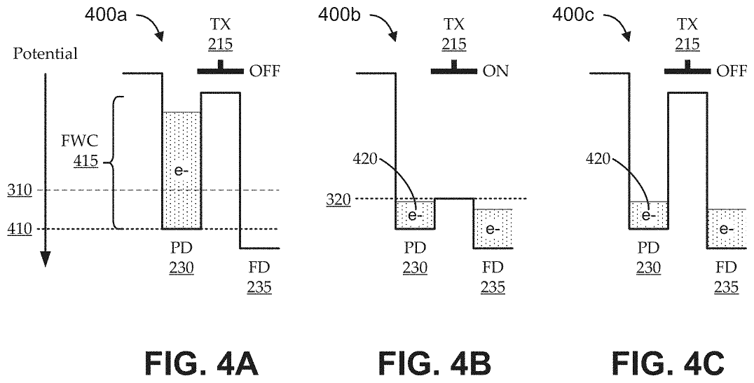

As can be seen in FIGS. 3A-3C, a large enough difference in potential between the VPmax 310 and the potential of the floating diffusion region 235 allows all of the accumulated photocharge to be transferred from the collection region 230 to the floating diffusion region 235 across the channel region. However, as described above, increasing VPmax 310 by too much can adversely impact such photocharge transfer. For example, FIGS. 4A-4C show a sequence of simplified energy band diagrams 400 to illustrate transfer of photocharges in a photodiode with an increased pinning voltage 410, as compared to the conventional pinning voltage 310 of FIGS. 3A-3C. The energy band diagrams 400 of FIGS. 4A — 4C are intended to be the same as those of FIGS. 3A-3C, except where stated otherwise.

Turning first to FIG. 4A, the transfer gate 215 is turned OFF, providing a barrier to allow for accumulation of photocharge in the collection region 230. It can be see that the increased pinning voltage 410 supports an appreciably larger FWC, as compared to using the conventional pinning voltage 310 (shown for reference). It can also be seen that the increased pinning voltage 410 is appreciably closer to the fully depleted potential of the floating diffusion region 235. Turning to FIG. 4B, after some exposure time, the transfer gate 215 is turned ON, and the channel potential in the channel region below the transfer gate 215 is pushed down to the same maximum channel potential 320 as in FIG. 3B. Because the increased pinning voltage 310 sits below the channel potential 320, some of the accumulated photocharge is not able to flow out of the collection region 230. Thus, while some of the accumulated photocharge flows into the floating diffusion region 235, a portion of the accumulated photocharge remains as residual photocharge 420 in the collection region 230. In FIG. 4C, after the transfer has occurred, the transfer gate 215 is turned OFF again, effectively trapping the transferred portion of the photocharge in the floating diffusion region 235, and also trapping the residual photocharge 420 in the collection region 230. This can be referred to as residue lag.

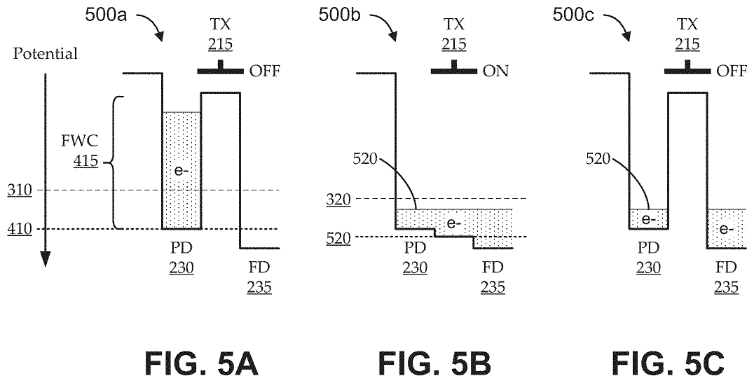

It may seem that such a concern can be addressed by increasing the channel potential 320 during transfer, but such an approach tends to result in a similar effect due to spill back. For example, FIGS. 5A-5C show another sequence of simplified energy band diagrams 500 to illustrate spill back during transfer of photocharges in a photodiode with an increased pinning voltage 410. The energy band diagrams 500 of FIGS. 5A-5C are intended to be the same as those of FIGS. 3A-4C, except where stated otherwise.

Turning first to FIG. 5A, the energy band diagram 500a is identical to that of FIG. 4A. The transfer gate 215 is turned OFF, providing a barrier to allow for accumulation of photocharge in the increased-FWC collection region 230. After some exposure time, the transfer gate 215 is turned ON in FIG. 5B. However, unlike in FIG. 4B, turning on the transfer gate 215 in FIG. 5B produces a higher channel potential 520 than the channel potential 320 in FIG. 3B and 4B (shown for reference). Because the potentials across the collection region 230, channel region and floating diffusion region 235 are so similar, the accumulated charge still does not fully transfer over to the floating diffusion region 235. Instead, some of the photocharge spills back into the collection region 230. In FIG. 5C, after the transfer has occurred and the transfer gate 215 is turned OFF again, the spilled-back portion of the photocharge is trapped as residual photocharge 520 in the collection region 230. The end result after transfer looks similar in FIGS. 4C and 5C. Regardless of the channel potential produced by turning on the transfer gate 215, residual photocharge 520 remains in the collection region 230, which manifests as lag and affects pixel performance.

Embodiments described herein introduce an additional gate structure, referred to as a well capacity adjustment gate (WCAG) that at least partially surrounds the photodiode well. Controlling the WCAG can effectively provide control over the pinning voltage of the photodiode, so that the pinning voltage can be different in different modes of operation. For example, in an integration mode, the WCAG is controlled to increase the pinning voltage potential, thereby increasing FWC. In a relay transfer mode, the WCAG is controlled to decrease the pinning voltage potential, thereby avoiding lag.

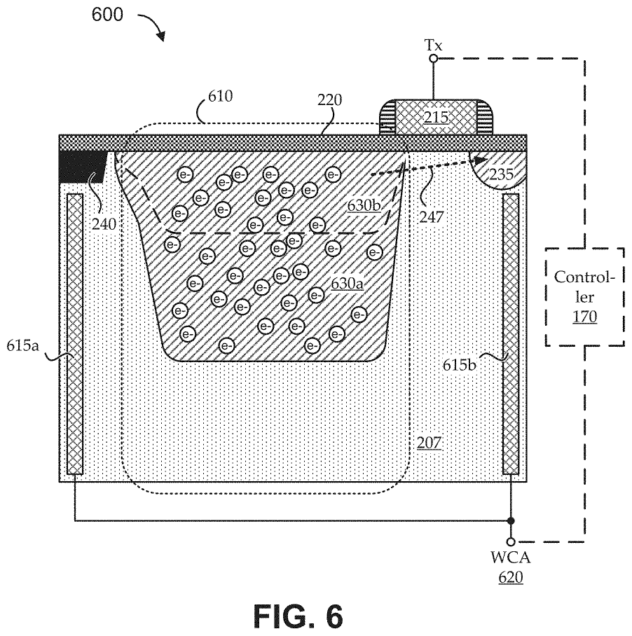

FIG. 6 shows an example of a novel well-capacity-adjustment-gate (WCAG) photo-sensor block 600, according to various embodiments described herein. The WCAG photo-sensor block 600 can be an implementation of the photo-sensor block 110 and/or the WCAG-PDs 115 shown in FIG. 1. As illustrated, the WCAG photo-sensor block 600 can be considered as including a photodiode region 610, a transfer gate 215, a floating diffusion region 235, and a WCAG 615. In some implementations, though not explicitly shown, the WCAG photo-sensor block 600 includes multiple photodiode regions 610 sharing a same floating diffusion region 235 via one or more transfer gates 215. The structures of the WCAG photo-sensor block 600 are implemented on a semiconductor substrate 207, such as a doped silicon wafer. While embodiments are described with reference to a p-doped substrate (i.e., with an n-doped well and electrons as photocharge carriers), the novel techniques described herein can similarly be applied in context of an n-doped substrate (i.e., with a p-doped well and holes as photocharge carriers).

The transfer gate 215 can be activated by a Tx signal and can be isolated from the substrate 207 by an oxide layer 220. The substrate 207 can have a first doping type (e.g., P-type). The photodiode region 610 can be formed by implanting at least a collection region 630 of a second doping type (e.g., N-type) into the substrate 207 on one side of the transfer gate 215. The floating diffusion region 235 can be implanted by doping a region using the second doping type (e.g., N-type) into the substrate 207 on the other side of the transfer gate 215. The collection region 630 is generally referred to herein as the “well” of the photodiode, and the maximum amount of photocharge that can be accumulated in the collection region 230 is the FWC. Isolation regions 240 (e.g., shallow-trench isolation, STI) can be formed to electrically isolate structures of the WCAG photo-sensor block 600 from those of adjacent structures, pixels, etc.

The illustrated wells and other structures of the WCAG photo-sensor block 600 are intended to provide clarity to the description, but are not intended to be accurate physical representations. For example, shapes and boundaries of structures implanted into the substrate are generally formed by etching, diffusion, and/or other processes, which may result in organically shaped regions with only statistically defined boundaries. Similarly, the actual amount of doping in different regions of the substrate may not match the effective structures that result from such doping. For example, the entire portion of the substrate 207 within the dashed photodiode region 610 may be doped with second-doping-type material, even though the effective collection region 630 only corresponds to a portion of the photodiode region 610.

As described with reference to FIG. 2, as photons reach the substrate 207 (i.e., during integration), they can be converted into photocarriers (i.e., electrons and holes), resulting in accumulation of photocharge in the collection region 630. Activating the Tx signal (i.e., turning on the transfer gate 215) can form a depletion region below the transfer gate 215, which effectively becomes a current channel between the two second-doping-type (e.g., N-type) regions: the collection region 630 and the floating diffusion region 235. As such, activation of the transfer gate 215 causes accumulated charge in the collection region 630 to transfer across the current channel to the floating diffusion region 235 (e.g., in the direction of arrow 247).

As illustrated, the WCAG 615 can include one or more deep trench structures. Some embodiments implement each WCAG 615 structure as a capacitive deep trench isolation region, such that each WCAG 615 structure is capacitively coupled with the photodiode region 610 (i.e., with the collection region 630). In some implementations, the WCAG 615 completely surrounds the photodiode region 610. For example, the illustrated WCAG 615 structures can represent two walls of a contiguous three-dimensional box around the photodiode region 610. In other implementations, the WCAG 615 partially surrounds the photodiode region 610. For example, the illustrated WCAG 615 structures can represent two of two or more walls on two or more sides of the photodiode region 610.

The WCAG 615 is coupled with a well capacity adjustment (WCA) terminal 620. Biasing of the WCAG 615 is controllable based on the voltage applied at the WCA terminal 620. For example, applying a positive voltage to the WCA terminal 620 can positively bias the WCAG 615 structures, effectively pulling down the pinning voltage potential and increasing the well size associated with the collection region 630 (represented as collection region 630a). Applying a negative voltage to the WCA terminal 620 can negatively bias the WCAG 615 structures, effectively pushing up the pinning voltage potential and decreasing the well size associated with the collection region 630 (represented as collection region 630b). As such, control of the WCAG 615 (via the WCA terminal 620) can effectively provide control over the FWC of the photodiode, such that the WCAG photo-sensor block 600 can operate in different modes with different associated FWCs.

As described with reference to FIG. 1, embodiments of the WCAG photo-sensor block 600 can be controlled by a controller 170. The controller 170 can provide signaling to set the transfer gate 215 and the WCAG 615 (via the WCA terminal 620) for implementing different modes of operation. The signaling can include voltage signals that provide respective biasing at respective terminals.

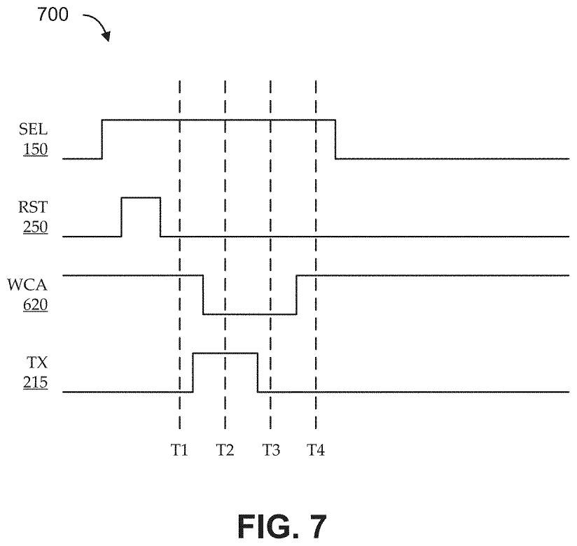

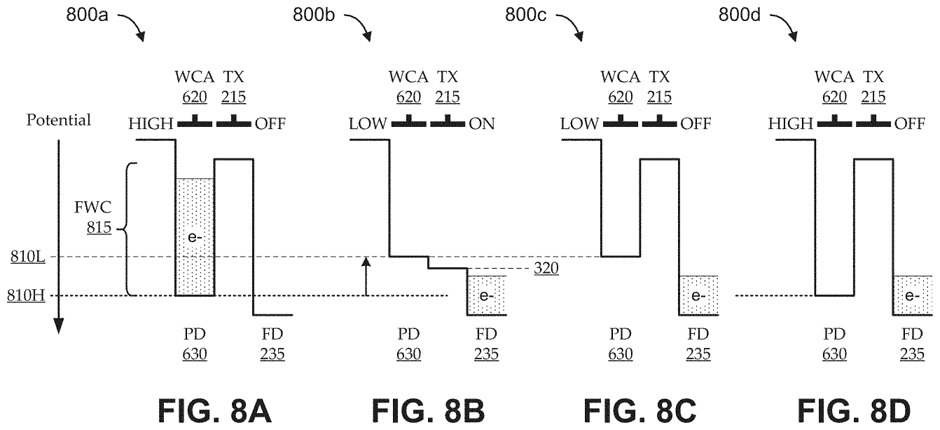

Some features of such multi-mode operation are described with reference to FIGS. 7 and 8A-8D, which are described in parallel for added clarity. FIG. 7 shows a simplified timing diagram 700 for controlling operation of a pixel that includes a WCAG photo-sensor block 600 during an illustrative charge integration and transfer cycle, according to various embodiments. FIGS. 8A-8D show a sequence of simplified energy band diagrams 800 to illustrate transfer of photocharge in a WCAG photo-sensor block 600, according to various embodiments. The timing diagram 700 shows three representative times, T1-T4, which correspond to FIGS. 8A-8D, respectively.

The timing diagram 700 shows an illustrative signal applied at the gate of the select block (SEL 150), an illustrative signal applied at the gate of the reset block (RST 250), an illustrative signal applied at the WCA terminal (WCA 620), and an illustrative signal applied at the transfer gate (TX 215). At the start of each cycle of operation, the SEL 150 signal is actuated to select the pixel having the WCAG photo-sensor block 600 of interest (e.g., as part of a row select operation, or the like). For example, the pixel is selected from among a large array of pixels, each with respective instances of the WCAG photo-sensor block 600. Next, the RST 250 signal is actuated for a short time to reset the pixel, such as flushing any accumulated charge left in the floating diffusion region 235 from a preceding cycle.

The WCAG photo-sensor block 600 is now ready for photocharge integration and transfer. During an integration time window, the WCAG photo-sensor block 600 is exposed to illumination, and photocharge accumulates in the collection region 630. Time T1 is a representative time within the integration time window. As illustrated, WCA 620 is HIGH and TX 215 is LOW during this time. FIG. 8A represents the energy band diagram for certain WCAG photo-sensor block 600 regions at time T1. With WCA 620 set to HIGH, the pinning voltage potential 810 is increased (represented as 810H). The well of the collection region 630 is effectively pushed down, thereby increasing FWC 815. With TX 215 turned OFF, a barrier is provided to allow for accumulation of photocharge in the collection region 630.

As illustrated in FIG. 7, after the integration time window (e.g., after some defined exposure time), a transfer time window occurs, during which WCA 620 switches to LOW and TX 215 switches to HIGH. Time T2 is a representative time within the transfer time window. FIG. 8B represents the energy band diagram at time T2. With WCA 620 set to LOW, the pinning voltage potential 810 is decreased (represented as 810L), which pulls up the well of the collection region 630 and decreases FWC 815. Turning TX 215 ON causes a depletion region to form in the channel region with a channel potential higher than that of the pulled up collection region 630 (i.e., higher than 810L), and lower than that of the floating diffusion region 235. As such, the photocharge that accumulated in the collection region 630 flows toward the lowest potential into the floating diffusion region 235. In some implementations, TX is turned ON prior (e.g., just prior) to switching WCA 620 to LOW to help ensure that the accumulated photocharge is able to move out of the collection region 630 prior to shrinking the collection region 630.

As illustrated in FIG. 7, after the transfer time window (e.g., after some defined exposure time), a spill-back suppression time window occurs, during which WCA 620 remains LOW while TX 215 switches back to LOW. Time T3 is a representative time within the spill-back suppression time window. FIG. 8C represents the energy band diagram at time T3. With WCA 620 and TX 215 both LOW, the channel region is effectively closed while the collection region 630 is still pulled up. This can help to ensure that all of the photocharge that transferred to the floating diffusion region 235 remains there without spilling back into the collection region 630.

Finally, as illustrated in FIG. 7, after the spill-back time window, a post-transfer time window can occur. During this window, WCA 620 can return to HIGH while TX 215 remains LOW. Time T4 is a representative time within the post-transfer time window. FIG. 8D represents the energy band diagram at time T4. With WCA 620 HIGH and TX 215 LOW, the energy band across the WCAG photo-sensor block 600 returns to a condition similar to that of FIG. 8A, except that all of the photocharge has been transferred across the channel to the floating diffusion region 235. Setting TX 215 to LOW can effectively close the transfer channel, so that transferred photocharge can remain in the floating diffusion region 235 ready for readout, and the FWC of the collection region 630 can return to its larger capacity in preparation for a subsequent integration time window in a subsequent cycle.

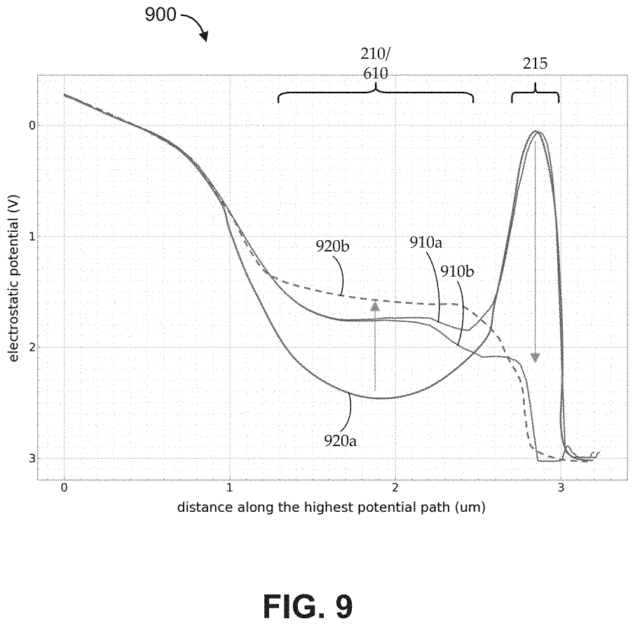

For added clarity, FIG. 9 shows a graph 900 of an illustrative set of plots comparing operation of a conventional type of photo-sensor block with a WCAG photo-sensor block 600. For reference, approximate regions are shown corresponding to the photodiode region (i.e., corresponding to region 210 for a conventional implementation and to 610 for a WCAG-based implementation as described herein) and the transfer gate 215 region. Following the convention of previous figures, the vertical axis shows electrostatic potential (referred to as “potential” throughout this disclosure), with the downward direction on the page corresponding to an increase in electrostatic potential.

Plots 910a and 910b represent operation of a conventional type of photo-sensor block during integration and transfer, respectively. In such a conventional implementation, TX 215 is OFF during integration, such that plot 910a shows a near-zero electrostatic potential (i.e., a potential barrier) in the transfer gate 215 region, and some well potential (e.g., around 1.75 volts) in the photodiode region 210. During transfer, TX 215 is ON, such that plot 910b shows a high electrostatic potential (e.g., around 3 volts, corresponding to a channel potential of a formed channel region) in the transfer gate 215 region, and approximately no change in the well potential (e.g., still around 1.75 volts) in the photodiode region 210. As illustrated, there can be some slight movement of the well potential close to the transfer gate 215 region due to fringe effects, or the like, but the well potential remains appreciably less than that of the channel potential. As noted above, such conventional designs purposefully design the well potential to stay appreciably less than that of the channel potential, such as to avoid lag concerns.

Plots 920a and 920b represent operation of a WCAG photo-sensor block 600 during integration and transfer, respectively. During integration, plot 910a shows that the electrostatic potential in the transfer gate 215 region can be substantially the same as for a conventional implementation, such that a potential barrier is formed. However, the photodiode region 210 is shown to be designed with a much greater potential of around 2.5 volts (i.e., corresponding to an appreciably larger FWC). During transfer, similar to the conventional case, plot 920b shows a high electrostatic potential corresponding to a channel potential of a formed channel region in the transfer gate 215 region. Unlike in the conventional case, plot 920b shows a large change in well potential (e.g., from around 2.5 volts to around 1.5 volts) in the photodiode region 210 during transfer facilitated by the novel configuration of the WCAG. For example, during integration, the WCAG can be biased so that the well potential is close to, or even below that of the channel potential (i.e., where the channel potential will be when TX 215 is ON during the transfer time window); and during transfer, the WCAG can be biased so that the well potential is decreased to a level far below that of the channel potential while the channel is ON.

Returning to FIG. 6, it can be seen that embodiments of the WCAG photo-sensor block 600 are configured for multi-mode operation by being configured selectively to operate in at least an integration mode (e.g., during an integration time window) and a transfer mode (e.g., during a transfer time window). The photodiode region 610 includes a doped well that manifests a collection region 630 and has an associated well capacity that is based on a particular well potential (i.e., a present electrostatic potential over the well). The floating diffusion region 235 is implanted to have a particular floating diffusion (FD) potential. The transfer gate 215 and channel region below the channel gate are configured, so that activation of the transfer gate 215 causes a current channel to form with a channel potential in the channel region between the doped well and the floating diffusion region 235. In general, in the transfer mode (i.e., during photocharge transfer, when the transfer gate 215 is activated to form the current channel), the FD potential is greater than the channel potential, which is greater than the well potential. In particular, the WCAG 615 is biased to effectively set the well potential to a such a level (e.g., far below that of the channel potential), which corresponds to a reduced well capacity as compared with the full well capacity during integration. Such a potential gradient across the device causes the photocharge (i.e., electrons, in this convention) accumulated in the collection region 630 to transfer over to the floating diffusion region 235 via the current channel as transferred photocharge. However, when selectively configured in the integration mode (i.e., prior to the transfer time window, when the photodiode is being exposed to incident illumination), the transfer gate 215 is OFF, and the WCAG 615 can be used to appreciably increase the well potential to a corresponding FWC. In such a condition, turning OFF the transfer gate 215 effectively forms a potential barrier (i.e., a near-zero electrostatic potential) between the collection region 630 and the floating diffusion region 235, such that the well potential can safely be pushed to a level still less than the channel potential, a level between the channel potential and the FD potential, or even a level greater than the FD potential.

As described above, the multi-mode operation can involve additional modes for some embodiments. Some embodiments of the WCAG photo-sensor block 600 are configured selectively to operate further in a spill-back suppression mode. For example, in the integration mode, the transfer gate 215 is set to be OFF to form the potential barrier between the doped well and the floating diffusion region 235 with the WCAG 615 set to be first-biased during accumulation of photocharge in the photodiode region 610. In the transfer mode, the transfer gate 215 is set to be ON to form the current channel between the doped well and the floating diffusion region 235 with the WCAG 615 set to be second-biased, such that accumulated photocharge transfers from the doped well to the floating diffusion region 235 via the current channel as transferred photocharge. In the spill-back suppression mode, the transfer gate 215 is set to be OFF to form the potential barrier between the doped well and the floating diffusion region 235 with the WCAG 615 set to be second-biased (i.e., kept in the second-biased state after the transfer time window is complete). Some embodiments are configured selectively to operate further in a readout mode, in which the transfer gate 215 is set to be OFF (e.g., or kept off after the spill-back suppression time window) to form (e.g., maintain) the potential barrier between the doped well and the floating diffusion region 235 during readout of the transferred photocharge from the floating diffusion region. For example, readout circuitry is directed to readout the transferred photocharge from the floating diffusion region 235 during the readout time window. In some such embodiments, the WCAG 615 set to be first-biased during the readout mode.

The WCAG 615 can be designed in different ways to provide features described herein. One or more WCA structures 615 are electrically coupled with a WCA terminal 620 (as illustrated) and form the walls that at least partially surround and capacitively couple with the doped well. The WCA terminal 620 receives a biasing signal to bias the WCA structures 615. In some embodiments, the one or more WCA structures 615 are implemented as a single contiguous deep-trench structure that is integrated with the semiconductor substrate 207 and forms the walls that at least partially surround and capacitively couple with the doped well. In other embodiments, the one or more WCA structures 65 are implemented as multiple deep-trench structures integrated with the semiconductor substrate 207, each forming one or more of the walls that at least partially surround and capacitively couple with the doped well.

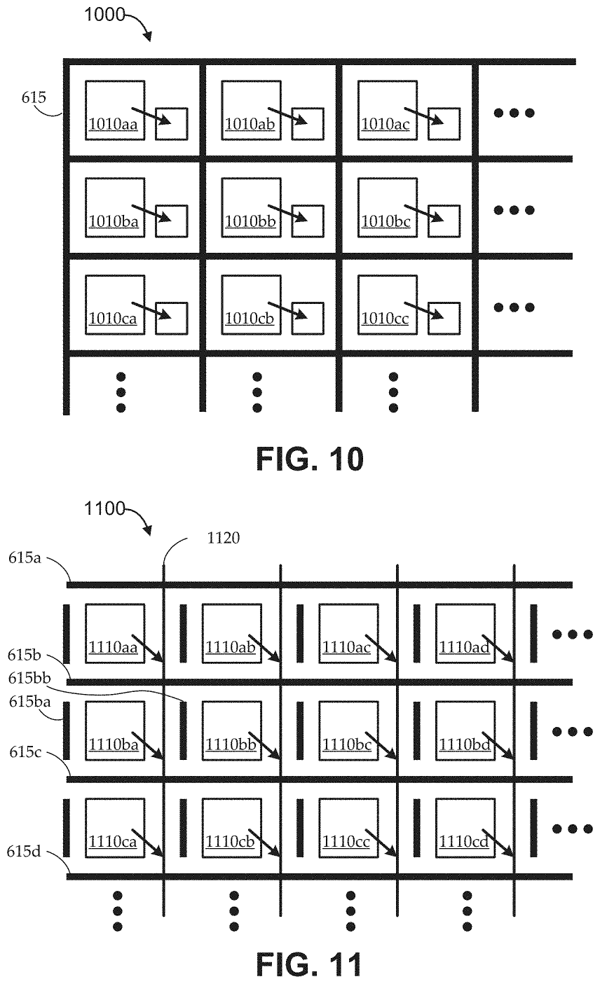

For example, FIG. 10 shows a simplified planar layout view 1000 of a partial array of pixels 1010 having a contiguous implementation of the WCA structures 615, according to various embodiments described herein. While the WCA structures 615 are described herein as part of the pixels 1010, they are shown separately from the pixels 1010 for the sake of clarity. Such a structure may be used for a pixel array that is configured for global shutter readout. For example, all of the pixels 1110 are configured with deep doped wells for accumulation of photocharge during integration. In such a configuration, accumulated charges in the pixels 1010 can be transferred to intermediate storage nodes for subsequent rolling readout. During such a global transfer, a global bias can be applied to the contiguous WCA structure 615 to reduce well capacity during the transfer window for protection against lag, and/or to provide other features described herein.

For example, FIG. 11 shows a simplified planar layout view 1100 of a partial array of pixels 1110 having a non-contiguous implementation of the WCA structures 615, according to various embodiments described herein. As in FIG. 10, the WCA structures 615 are shown as separate from the pixels 1110 for the sake of clarity. Because the WCA structures 615 are not contiguous, forming a surrounding wall of WCA structures 615 for any particular pixel 1110 can involve controlling the WCA structures 615 adjacent to some or all sides of that pixel 1110.

Such a structure may be used for a pixel array that is configured for rolling shutter readout. For example, all of the pixels 1110 are configured with deep doped wells for accumulation of photocharge during integration. When it is time to transfer and readout pixel 1110ba (e.g., to a readout line, such as line 1120), some or all of WCA structures 615b, 615c, 615ba, and 615bb can be biased together to form walls on some or all sides of the doped well. For example, all the WCA structures 615 for a particular row can be biased together to support row-wise readout. In this way, selectively biasing different sets of WCA structures 615 can provide individualized control over the well potential of particular pixels 1110. For example, because WCA structure 615b is adjacent to both pixel 1110ba and 1110aa, such that biasing WCA structure 615b for readout of pixel 1110ba also incidentally biases one of the WCA structures 615 adjacent to pixel 1110aa. However, biasing only the single adjacent WCA structure 615 can be insufficient to appreciably change the well potential for pixel 1110aa, such that pixel 1110aa can still integrate properly during readout of pixel 1110ba. To reduce biasing effects on adjacent pixels 1110, some embodiments also add biasing to the adjacent transfer gates. For example, while the second row of pixels 1110ba . . . 1110bn is being readout (i.e., and the WCA structures 615 adjacent to the sides of all the pixels 1110 in that row are biased to reduce well potentials), transfer gates for the first row of pixels 1110aa . . . 1110an and the third row of pixels 1110ca . . . 1110cn can be slightly biased (e.g., negatively) to further pull up the potential barrier. In other embodiments a non-contiguous arrangement of WCA structures can be used with a global shutter readout scheme.

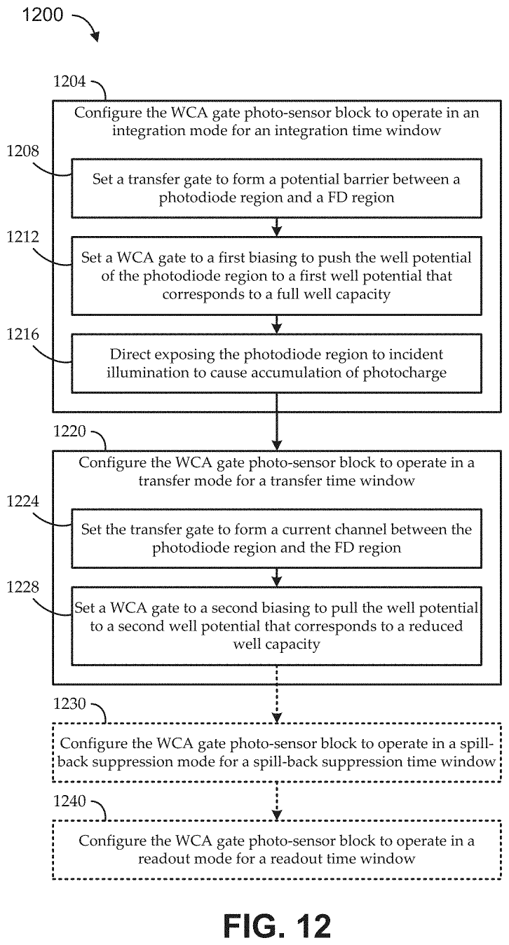

FIG. 12 shows a flow diagram of an illustrative method 1200 for selective photodiode well capacity adjustment in an imaging sensor pixel, according to embodiments described herein. Embodiments of the method 1200 can be implemented using any embodiments of well-capacity-adjustment (WCA) gate photo-sensor blocks, such as WCA gate photo-sensor block 600. Embodiments begin at stage 1204 by configuring the WCA gate photo-sensor block to operate in an integration mode for an integration time window. As illustrated, stage 1204 can involve a number of internal stages, such as stages 1208-1216.

For example, at stage 1208, embodiments can set a transfer gate of the WCA gate photo-sensor block (as part of the integration mode of operation) to form a potential barrier between a photodiode region of the WCA gate photo-sensor block and a floating diffusion (FD) region of the WCA gate photo-sensor block. As used herein, the term “potential” refers to electrostatic potential, such that a term like “potential barrier” refers to a region of sufficiently low (e.g., near-zero) electrostatic potential as to ensure that photocharge does not transfer from one region to another. As described above, the photodiode region has a doped well implanted in a semiconductor substrate (e.g., a collection region) that has a well capacity defined at least by a well potential.

At stage 1212, embodiments can set a WCA gate of the WCA gate photo-sensor block (as part of the integration mode of operation) to a first biasing. As described above, the WCA gate is integrated in the semiconductor substrate to form walls that at least partially surround and capacitively couple with the doped well. Due to such capacitive coupling, the first biasing of the WCA gate pushes the well potential of the doped well to a first well potential that corresponds to a full well capacity. As described herein, the well potential in this mode can be higher (i.e., to FWC can be higher) than in conventional approaches. For example, the first well potential can be greater than the channel potential, and/or the first well potential can even be greater than the FD potential. At stage 1216, embodiments can direct exposing the photodiode region (as part of the integration mode of operation) to incident illumination to cause accumulation of photocharge in the doped well during the integration time widow. Such directing can involve permitting an exposure time to elapse, controlling a shutter, etc.

Embodiments of the method 1200 can continue at stage 1220 by configuring the WCA gate photo-sensor block to operate in a transfer mode for a transfer time window subsequent to the integration time window. As illustrated, stage 1220 can involve a number of internal stages, such as stages 1224-1228. At stage 1224, embodiments can set the transfer gate (as part of the transfer mode of operation) to form a current channel between the doped well and the FD region. For example, a TX signal is sent to the transfer gate to turn the gate ON, thereby causing a depletion region to form below the transfer gate between the doped well and the FD region. At stage 1228, embodiments can set the WCA gate (as part of the transfer mode of operation) to a second biasing to pull the well potential to a second well potential that corresponds to a reduced well capacity. The second well potential is less than a channel potential of the current channel, which is less than a FD potential of the FD region, such that a gradient is formed between the doped well and the FD region. In some embodiments, the setting of the transfer gate in stage 1224 is performed prior to the setting of the WCA gate in stage 1228. For example, in cases where the first well potential is greater than the channel potential, performance of stage 1224 prior to performance of stage 1228 can help to avoid residue lag, and/or other concerns.

Some embodiments of the method 1200 include additional stages to provide for additional modes of operation of the WCA gate photo-sensor block. In some embodiments, at stage 1230, the method 1200 can configure the WCA gate photo-sensor block to operate in a spill-back suppression mode for a spill-back suppression time window subsequent to the transfer time window. For example, the configuring in stage 1220 can cause photocharge accumulated in the doped well during the integration time window to transfer to the FD region via the current channel as transferred photocharge. As such, the configuring at stage 1230 can be performed by re-setting the transfer gate to form the potential barrier between the doped well and the FD region (as in stage 1208) while continuing to set the WCA gate to the second biasing.

In some embodiments, at stage 1240, the method 1200 can further configure the WCA gate photo-sensor block to operate in a readout mode for a readout time window subsequent to the spill-back suppression time window. Such configuring can include directing readout of the transferred photocharge from the FD region by readout circuitry coupled with the FD region with the transfer gate set to form the potential barrier. In some implementations, the configuring at stage 1240 also includes re-setting the WCA gate to the first biasing (i.e., to the increased FWC) during the readout time window. As described above, readout during such a readout mode can be performed in different ways for different pixel configurations, such as using a global shutter readout or a rolling shutter readout. The manner of setting the WCA gate in at least stage 1228 can be to support the different types of readout. For example, all WCA gate structures for all pixels may be concurrently biased in global shutter readout implementations, while sets of WCA gate structures adjacent to particular pixels may be biased in a particular sequence to support rolling shutter readout implementations.

As used herein, reference to “first biasing” and “second biasing” intends to convey a first biasing state and a second biasing state, where the second biasing state is sufficiently different from the first biasing state to provide the corresponding features described herein. In some implementations, one of the biasing states corresponds to a logic HIGH (e.g., a digital ‘1’), and the other corresponds to a logic LOW (e.g., a digital ‘0’). In other implementations, one of the biasing states corresponds to positive voltage level, and the other corresponds to a negative voltage level. In other implementations, one of the biasing states corresponds to positive or negative voltage level, and the other corresponds to a zero (or substantially zero) voltage level. For example, the doped well can be doped and implanted in a manner that provides a very deep well without any biasing on the WCA gate structures, such that setting the WCA gate to the first biasing (e.g., as in stage 1212) can involve removing biasing from the WCA gate and setting the WCA gate to the second biasing (e.g., as in stage 1228) can involve actively biasing the WCA gate. Alternatively, the doped well can be doped and implanted in a manner that provides a very deep well only with the help of biasing on the WCA gate structures, such that setting the WCA gate to the first biasing can involve actively biasing the WCA gate and setting the WCA gate to the second biasing can involve removing biasing from the WCA gate.

It will be understood that, when an element or component is referred to herein as “connected to” or “coupled to” another element or component, it can be connected or coupled to the other element or component, or intervening elements or components may also be present. In contrast, when an element or component is referred to as being “directly connected to,” or “directly coupled to” another element or component, there are no intervening elements or components present between them. It will be understood that, although the terms “first,” “second,” “third,” etc. may be used herein to describe various elements, components, these elements, components, regions, should not be limited by these terms. These terms are only used to distinguish one element, component, from another element, component. Thus, a first element, component, discussed below could be termed a second element, component, without departing from the teachings of the present invention. As used herein, the terms “logic low,” “low state,” “low level,” “logic low level,” “low,” or “0” are used interchangeably. The terms “logic high,” “high state,” “high level,” “logic high level,” “high,” or “1” are used interchangeably.

As used herein, the terms “a”, “an” and “the” may include singular and plural references. It will be further understood that the terms “comprising”, “including”, having” and variants thereof, when used in this specification, specify the presence of stated features, steps, operations, elements, and/or components, but do not preclude the presence or addition of one or more other features, steps, operations, elements, components, and/or groups thereof. In contrast, the term “consisting of” when used in this specification, specifies the stated features, steps, operations, elements, and/or components, and precludes additional features, steps, operations, elements and/or components. Furthermore, as used herein, the words “and/or” may refer to and encompass any possible combinations of one or more of the associated listed items.

While the present invention is described herein with reference to illustrative embodiments, this description is not intended to be construed in a limiting sense. Rather, the purpose of the illustrative embodiments is to make the spirit of the present invention be better understood by those skilled in the art. In order not to obscure the scope of the invention, many details of well-known processes and manufacturing techniques are omitted. Various modifications of the illustrative embodiments, as well as other embodiments, will be apparent to those of skill in the art upon reference to the description. It is therefore intended that the appended claims encompass any such modifications.

Furthermore, some of the features of the preferred embodiments of the present invention could be used to advantage without the corresponding use of other features. As such, the foregoing description should be considered as merely illustrative of the principles of the invention, and not in limitation thereof. Those of skill in the art will appreciate variations of the above-described embodiments that fall within the scope of the invention. As a result, the invention is not limited to the specific embodiments and illustrations discussed above, but by the following claims and their equivalents.

What is claimed is:

1. A method for selective photodiode well capacity adjustment in an imaging sensor pixel, the method comprising:
first configuring the WCA gate photo-sensor block to operate in an integration mode for an integration time window by:
setting a transfer gate of a well-capacity-adjustment (WCA) gate photo-sensor block to form a potential barrier between a photodiode region of the WCA gate photo-sensor block and a floating diffusion (FD) region of the WCA gate photo-sensor block, the photodiode region having a doped well implanted in a semiconductor substrate to have a well capacity defined at least by a well potential;
setting a WCA gate of the WCA gate photo-sensor block to a first biasing, the WCA gate integrated in the semiconductor substrate to form walls that at least partially surround and capacitively couple with the doped well, such that the first biasing pushes the well potential to a first well potential that corresponds to a full well capacity; and
directing exposing the photodiode region to incident illumination to cause accumulation of photocharge in the doped well during the integration time widow;
second configuring the WCA gate photo-sensor block to operate in a transfer mode for a transfer time window subsequent to the integration time window by:
setting the transfer gate to form a current channel between the doped well and the FD region; and
setting the WCA gate to a second biasing to pull the well potential to a second well potential that corresponds to a reduced well capacity, the second well potential being less than a channel potential of the current channel, the channel potential being less than a FD potential of the FD region.

2. The method of claim 1, wherein the first well potential is greater than the channel potential.

3. The method of claim 1, wherein the first well potential is greater than the FD potential.

4. The method of claim 1, wherein the second configuring comprises performing the setting the transfer gate to form the current channel prior to setting the WCA gate to the second biasing.

5. The method of claim 1, wherein the second configuring causes the photocharge accumulated in the doped well during the integration time window to transfer to the FD region via the current channel as transferred photocharge, and further comprising:
third configuring the WCA gate photo-sensor block to operate in a spill-back suppression mode for a spill-back suppression time window subsequent to the transfer time window by re-setting the transfer gate to form the potential barrier between the doped well and the FD region while continuing the setting of the WCA gate to the second biasing.

6. The method of claim 5, further comprising:
fourth configuring the WCA gate photo-sensor block to operate in a readout mode for a readout time window subsequent to the spill-back suppression time window by directing readout of the transferred photocharge from the FD region by readout circuitry coupled with the FD region with the transfer gate set to form the potential barrier.

7. The method of claim 6, wherein the fourth configuring further comprises:
re-setting the WCA gate to the first biasing during the readout time window.

8. A imaging sensor pixel comprising:
a well-capacity-adjustment (WCA) gate photo-sensor block configured selectively to operate in at least an integration mode and a transfer mode, the WCA gate photo-sensor block comprising:
a photodiode region having a doped well implanted into a semiconductor substrate to accumulate photocharge responsive to exposure of the WCA gate photo-sensor block to incident illumination, the doped well having a well capacity defined at least by a well potential;
a WCA gate integrated in the semiconductor substrate to form walls that at least partially surround and capacitively couple with the doped well, such that the well potential is based at least on biasing of the WCA gate;
a floating diffusion (FD) region implanted into the semiconductor substrate to have a FD potential; and
a transfer gate to selectively form a current channel between the doped well and the floating diffusion region, the current channel having a channel potential less than the FD potential,
wherein, in the integration mode, the WCA gate is first-biased to set the well potential to a first well potential corresponding to a full well capacity, and
wherein, in the transfer mode, the WCA gate is second-biased to set the well potential to a second well potential that is less than the first well potential, is less than the channel potential, and corresponds to a reduced well capacity.

9. The imaging sensor pixel of claim 8, wherein the first well potential is greater than the channel potential.

10. The imaging sensor pixel of claim 1, wherein the first well potential is greater than the FD potential.

11. The imaging sensor pixel of claim 8, wherein:
the WCA gate photo-sensor block is configured selectively to operate further in a spill-back suppression mode;
in the integration mode, the transfer gate is set to be OFF to form a potential barrier between the doped well and the floating diffusion region with the WCA gate set to be first-biased during accumulation of photocharge in the photodiode region;
in the transfer mode, the transfer gate is set to be ON to form the current channel between the doped well and the floating diffusion region with the WCA gate set to be second-biased, such that accumulated photocharge transfers from the doped well to the floating diffusion region via the current channel as transferred photocharge; and
in the spill-back suppression mode, the transfer gate is set to be OFF to form the potential barrier between the doped well and the floating diffusion region with the WCA gate set to be second-biased.

12. The imaging sensor pixel of claim 11, wherein:
the WCA gate photo-sensor block is configured selectively to operate further in a readout mode;
in the readout mode, the transfer gate is set to be OFF to form the potential barrier between the doped well and the floating diffusion region with the WCA gate set to be first-biased during readout of the transferred photocharge from the floating diffusion region.

13. The imaging sensor pixel of claim 8, wherein:
the WCA gate comprises one or more WCA structures electrically coupled with a WCA terminal and forming the walls that at least partially surround and capacitively couple with the doped well, the WCA terminal configured to receive a biasing signal to bias the WCA structures.

14. The imaging sensor pixel of claim 13, wherein:
the one or more WCA structures comprise a single contiguous deep-trench structure that is integrated with the semiconductor substrate and forms the walls that at least partially surround and capacitively couple with the doped well.

15. The imaging sensor pixel of claim 13, wherein:
the one or more WCA structures comprise a plurality of deep-trench structures integrated with the semiconductor substrate, each of the deep-trench structures forming one or more of the walls that at least partially surround and capacitively couple with the doped well.

16. The imaging sensor pixel of claim 8, wherein:
the photodiode region is configured as a pinned photodiode, and the well potential is the pinning voltage of the pinned photodiode.

17. A complementary metal-oxide semiconductor (CMOS) imaging sensor (CIS) comprising:
an array of imaging pixels, each imaging pixel comprising a well-capacity-adjustment (WCA) gate photo-sensor block, each WCA gate photo-sensor block comprising:
a photodiode region having a doped well implanted into a semiconductor substrate to accumulate photocharge responsive to exposure of the WCA gate photo-sensor block to incident illumination, the doped well having a well capacity defined at least by a well potential;
a WCA gate integrated in the semiconductor substrate to form walls that at least partially surround and capacitively couple with the doped well, such that the well potential is based at least on biasing of the WCA gate;
a floating diffusion (FD) region implanted into the semiconductor substrate to have a FD potential; and
a transfer gate to selectively form a current channel between the doped well and the floating diffusion region, the current channel having a channel potential less than the FD potential; and
a controller coupled with the array of imaging pixels to selectively configure each imaging pixel to operate in at least an integration mode and a transfer mode, such that:
the controller is to configure each imaging pixel to operate in the integration mode by setting the transfer gate of the imaging pixel to form a potential barrier between the doped well of the imaging pixel and the FD region of the imaging pixel, setting the WCA gate of the imaging pixel to a first biasing to push the well potential of the imaging pixel to a first well potential that corresponds to a full well capacity, and directing exposing the imaging pixel to incident illumination to cause accumulation of photocharge in the doped well of the imaging pixel during an integration time widow; and
the controller is to configure each imaging pixel to operate in the transfer mode by setting the transfer gate of the imaging pixel to form a current channel between the doped well of the imaging pixel and the FD region of the imaging pixel, and setting the WCA gate of the imaging pixel to a second biasing to pull the well potential of the imaging pixel to a second well potential that corresponds to a reduced well capacity, the second well potential being less than a channel potential of the current channel, the channel potential being less than a FD potential of the FD region.

18. The CIS of claim 17, wherein:
the configuring each imaging pixel to operate in the transfer mode causes the photocharge accumulated in the doped well during the integration time window to transfer to the FD region via the current channel as transferred photocharge; and
the controller is further to configure each imaging pixel to operate in a spill-back suppression mode for a spill-back suppression time window subsequent to the transfer time window by re-setting the transfer gate of the imaging pixel to form the potential barrier between the doped well of the imaging pixel and the FD region of the imaging pixel while continuing the setting of the WCA gate of the imaging pixel to the second biasing.

19. The CIS of claim 18, wherein:
the controller is further to configure each imaging pixel to operate in a readout mode for a readout time window subsequent to the spill-back suppression time window by directing readout of the transferred photocharge from the FD region by readout circuitry coupled with the FD region with the transfer gate set to form the potential barrier.

20. The CIS of claim 17, wherein:
the controller is to configure a plurality of imaging pixels concurrently to operate in the transfer mode by setting the WCA gate to the second biasing to concurrently pull the well potentials of the plurality of imaging pixels to the second well potential; and
the controller is further to direct readout of the array of imaging pixels according to a global shutter readout routine.

21. The CIS of claim 17, wherein:
the controller is further to direct readout of the array of imaging pixels according to a rolling shutter readout routine that defines a readout sequence;
the WCA gate comprises non-contiguous WCA structures that are independently controllable by the controller, each of the imaging pixels surrounded by a respective set of the non-contiguous WCA structures; and
the controller is to configure each imaging pixel to operate in the transfer mode by setting the WCA gate to the second biasing by identifying the respective set of the non-contiguous WCA structures that surrounds the doped well of the imaging pixel, and independently setting only the respective set of the non-contiguous WCA structures to the second biasing in accordance with the readout sequence.
the controller is further to direct readout of the array of imaging pixels according to a global shutter readout routine.
